(19) United States
(12) Patent Application Publication
(10) Pub. No.: US 2025/0095719 A1
(43) Pub. Date: Mar. 20, 2025

(54) RESISTANCE CALIBRATION CIRCUIT, RESISTANCE CALIBRATION METHOD, AND MEMORY

(71) Applicant: CXMT CORPORATION, Hefei (CN)

(72) Inventors: Xi WANG, Hefei (CN); Kai TIAN, Hefei (CN)

(21) Appl. No.: 18/950,189

(22) Filed: Nov. 18, 2024

Related U.S. Application Data
(63) Continuation of application No. PCT/CN2023/098105, filed on Jun. 2, 2023.

(30) Foreign Application Priority Data
Mar. 3, 2023 (CN) 202310197194.8

(51) Int. Cl. G11C 11/4093; G11C 11/4076; H03K 19/20

(52) U.S. Cl. CPC G11C 11/4093; G11C 11/4076; G11C 2207/2254; H03K 19/20

(57) ABSTRACT

Provided are a resistance calibration circuit, a resistance calibration method, and a memory. When a short calibration enable signal is valid, calibration processing is performed on a resistance control code in one of a short calibration mode and a full calibration mode based on a comparison result of a last latched value and an initial default value of the resistance control code.

### CROSS-REFERENCES TO RELATED APPLICATIONS

This application is a continuation of International Patent Application No. PCT/CN2023/098105, filed on Jun. 2, 2023, which claims the benefit of Chinese Patent Application No. 202310197194.8, titled “RESISTANCE CALIBRATION CIRCUIT, RESISTANCE CALIBRATION METHOD, AND MEMORY”, filed with the China National Intellectual Property Administration (CNIPA) on Mar. 3, 2023, the disclosures of which are incorporated herein by reference in their entireties.

### TECHNICAL FIELD

The present disclosure relates to but is not limited to a resistance calibration circuit, a resistance calibration method, and a memory.

### BACKGROUND

Some output driver circuits are required to implement output driving or termination processing of signals in a working process of a dynamic random access memory (DRAM). It should be understood that the memory needs to calibrate resistance of related equivalent resistance because equivalent resistance of the output driver circuit changes with an environment parameter (e.g., a temperature or a voltage), which is referred to as ZQ calibration. However, current ZQ calibration occupies too much power consumption and system time, reducing performance of the memory.

### SUMMARY

The present disclosure provides a resistance calibration circuit, a resistance calibration method, and a memory.

The technical solutions of the present disclosure are implemented as follows.

According to a first aspect, an embodiment of the present disclosure provides a resistance calibration circuit. The resistance calibration circuit includes:
a register circuit, configured to store and output a short calibration enable signal; a comparison circuit, configured to: receive a last latched value and an initial default value of a resistance control code, perform a consistency comparison between the last latched value and the initial default value of the resistance control code, and output a comparison result signal; a logic circuit, configured to: receive the short calibration enable signal and the comparison result signal, perform a logical operation on the short calibration enable signal and the comparison result signal, and output a mode selection signal; and a calibration circuit, configured to: perform calibration processing on the resistance control code in one of a short calibration mode and a full calibration mode based on the mode selection signal when a calibration start signal is received, and perform latching processing on the resistance control code after calibration processing is completed. Both the register circuit and the comparison circuit are connected to the logic circuit, and the logic circuit is connected to the calibration circuit.

In some embodiments, the comparison circuit is specifically configured to: output the comparison result signal in a first state when the last latched value and the initial default value of the resistance control code are different; or output the comparison result signal in a second state when the last latched value and the initial default value of the resistance control code are the same. A logic potential in the first state is different from a logic potential in the second state.

In some embodiments, the logic circuit is specifically configured to: output the mode selection signal in a fifth state when the short calibration enable signal is in a fourth state; or output the mode selection signal in a sixth state when the short calibration enable signal is in a third state and the comparison result signal is in the first state; or output the mode selection signal in a fifth state when the short calibration enable signal is in a third state and the comparison result signal is in the second state. A logic potential in the third state is different from a logic potential in the fourth state, the short calibration enable signal in the third state indicates to enable the short calibration mode, the short calibration enable signal in the fourth state indicates to disable the short calibration mode, and a logic potential in the fifth state is different from a logic potential in the sixth state.

In some embodiments, the calibration circuit is specifically configured to: when the calibration start signal is received, perform calibration processing on the resistance control code in the full calibration mode if the mode selection signal is in the fifth state, or perform calibration processing on the resistance control code in the short calibration mode if the mode selection signal is in the sixth state; and output a new latched value of the resistance control code, a change recording signal, and a calibration end signal after calibration processing is ended. The change recording signal indicates whether the latched value of the resistance control code changes.

In some embodiments, the resistance control code includes a pull-up control code and a pull-down control code, the initial default value includes a pull-up default value and a pull-down default value, and the calibration processing includes pull-up calibration processing and pull-down calibration processing. In the short calibration mode, a start point of the pull-up calibration processing is a last latched value of the pull-up control code, and a start point of the pull-down calibration processing is a last latched value of the pull-down control code. In the full calibration mode, a start point of the pull-up calibration processing is the pull-up default value, and a start point of the pull-down calibration processing is the pull-down default value.

In some embodiments, the calibration circuit includes: a control code generation module, configured to generate the pull-up control code and the pull-down control code based on the mode selection signal; a resistor module, including a resistor unit, and configured to: control resistance of the resistor unit based on the pull-up control code and the pull-down control code, and generate and output a resistance comparison signal, the resistance comparison signal indicating a value relationship between the resistance of the resistor unit and standard resistance; and a control module, configured to: determine, based on the resistance comparison signal, whether pull-up calibration processing or pull-down calibration processing is completed; and output the calibration end signal and the change recording signal after both pull-up calibration processing and pull-down calibration processing are completed. The control code generation module is further configured to: latch the resistance control code when a latch command signal is received, and generate a new latched value of the resistance control code. The latch command signal is generated after both the pull-up calibration processing and the pull-down calibration processing are completed. The control code generation module is connected to the resistor module, and the resistor module is connected to the control module.

In some embodiments, the control code generation module includes: a selection module, configured to: receive the mode selection signal, the pull-up default value, the pull-down default value, the last latched value of the pull-up control code, and the last latched value of the pull-down control code; and output the pull-up default value as a pull-up initial value, and output the pull-down default value as a pull-down initial value, if the mode selection signal is in the fifth state; or output the last latched value of the pull-up control code as a pull-up initial value, and output the last latched value of the pull-down control code as a pull-down initial value, if the mode selection signal is in the sixth state; and an adjustment module, connected to the selection module, and configured to: generate the pull-up control code and the pull-down control code based on the pull-up initial value and the pull-down initial value; adjust the pull-down control code in a process of the pull-down calibration processing; and adjust the pull-up control code in a process of the pull-up calibration processing.

In some embodiments, the control module is further configured to: receive the calibration start signal, and output a pull-down enable signal and a pull-up enable signal based on the calibration start signal. A valid pull-down enable signal indicates to perform pull-down calibration processing, a valid pull-up enable signal indicates to perform pull-up calibration processing, and a maximum of only one of the pull-down enable signal and the pull-up enable signal is valid. The resistor module further includes a reference unit and a comparator. The resistor unit is configured to: receive the pull-up control code and the pull-down control code, and output a first voltage signal. The reference unit is connected to the control module, and is configured to output a reference voltage signal based on the pull-down enable signal and the pull-up enable signal. The comparator is connected to the resistor unit and the reference unit, and is configured to: receive the first voltage signal and the reference voltage signal; and output the resistance comparison signal in a seventh state if the first voltage signal is greater than the reference voltage signal; or output the resistance comparison signal in an eighth state if the first voltage signal is not greater than the reference voltage signal. A logic potential in the seventh state is different from a logic potential in the eighth state.

In some embodiments, the calibration circuit further includes a clock module. The clock module is configured to output a calibration clock signal based on the calibration start signal. The adjustment module is further configured to: receive the calibration clock signal and the resistance comparison signal; perform addition or subtraction processing on the pull-up control code based on the resistance comparison signal in each clock cycle of the calibration clock signal in the process of the pull-up calibration processing; and perform addition or subtraction processing on the pull-down control code based on the resistance comparison signal in each clock cycle of the calibration clock signal in the process of the pull-down calibration processing. The control module is further configured to: record a change status of the resistance comparison signal in each clock cycle of the calibration clock signal; determine that pull-down calibration is completed if a change of the resistance comparison signal meets a target end condition in the process of the pull-down calibration processing; and determine that pull-up calibration is completed if a change of the resistance comparison signal meets a target end condition in the process of the pull-up calibration processing. Both the control code generation module and the control module are connected to the clock module, and the control code generation module is further connected to the resistor module.

In some embodiments, the control module is further configured to output an internal end signal after both the pull-up calibration processing and the pull-down calibration processing are completed. The clock module is further configured to: receive the internal end signal, and stop, based on the internal end signal, outputting the calibration clock signal.

In some embodiments, the control module is specifically configured to: receive the mode selection signal; and determine one of a preset full calibration end condition and a preset short calibration end condition as the target end condition based on the mode selection signal.

In some embodiments, in the short calibration mode, the pull-down calibration processing occupies two clock cycles; and correspondingly, when the mode selection signal is in the sixth state: the adjustment module is specifically configured to: perform a subtraction by one operation on an internal bit of the pull-down control code if the resistance comparison signal is in the seventh state in the 1st clock cycle of pull-down calibration processing, and continue to perform the subtraction by one operation on the internal bit of the pull-down control code if the resistance comparison signal is still in the seventh state in the 2nd clock cycle of pull-down calibration processing; or perform a subtraction by one operation on an internal bit of the pull-down control code if the resistance comparison signal is in the seventh state in the 1st clock cycle of pull-down calibration processing, and perform an addition by one operation on the internal bit of the pull-down control code if the resistance comparison signal is in the eighth state in the 2nd clock cycle of pull-down calibration processing; or perform an addition by one operation on an internal bit of the pull-down control code if the resistance comparison signal is in the eighth state in the 1st clock cycle of pull-down calibration processing, and continue to perform the addition by one operation on the internal bit of the pull-down control code if the resistance comparison signal is still in the eighth state in the 2nd clock cycle of pull-down calibration processing; or perform an addition by one operation on an internal bit of the pull-down control code if the resistance comparison signal is in the eighth state in the 1st clock cycle of pull-down calibration processing, and perform a subtraction by one operation on the internal bit of the pull-down control code if the resistance comparison signal is in the seventh state in the 2nd clock cycle of pull-down calibration processing. The internal bit of the pull-down control code is a smallest bit of the pull-down control code, and the internal bit of the pull-down control code is not open to a user.

In some embodiments, in the short calibration mode, the pull-up calibration processing occupies two clock cycles; and correspondingly, when the mode selection signal is in the sixth state: the adjustment module is specifically configured to: perform a subtraction by one operation on an internal bit of the pull-up control code if the resistance comparison signal is in the seventh state in the 1st clock cycle of pull-up calibration processing, and continue to perform the subtraction by one operation on the internal bit of the pull-up control code if the resistance comparison signal is still in the seventh state in the 2nd clock cycle of pull-up calibration processing; or perform a subtraction by one operation on an internal bit of the pull-up control code if the resistance comparison signal is in the seventh state in the 1st clock cycle of pull-up calibration processing, and perform an addition by one operation on the internal bit of the pull-up control code if the resistance comparison signal is in the eighth state in the 2nd clock cycle of pull-up calibration processing; or perform an addition by one operation on an internal bit of the pull-up control code if the resistance comparison signal is in the eighth state in the 1st clock cycle of pull-up calibration processing, and continue to perform the addition by one operation on the internal bit of the pull-up control code if the resistance comparison signal is still in the eighth state in the 2nd clock cycle of pull-up calibration processing; or perform an addition by one operation on an internal bit of the pull-up control code if the resistance comparison signal is in the eighth state in the 1st clock cycle of pull-up calibration processing, and perform a subtraction by one operation on the internal bit of the pull-up control code if the resistance comparison signal is in the seventh state in the 2nd clock cycle of pull-up calibration processing. The internal bit of the pull-up control code is a smallest bit of the pull-up control code, and the internal bit of the pull-up control code is not open to the user.

In some embodiments, the first state, the third state, the fifth state, and the seventh state are high level states, and the second state, the fourth state, the sixth state, and the eighth state are low level states. The logic circuit includes a NAND gate, and two input terminals of the NAND gate respectively receive the short calibration enable signal and the comparison result signal.

According to a second aspect, an embodiment of the present disclosure provides a resistance calibration method. The method includes the steps as follows.

Calibration processing is performed on a resistance control code in a full calibration mode when a short calibration mode is disabled; or calibration processing is performed on a resistance control code in a short calibration mode if a last latched value and an initial default value of the resistance control code are different when the short calibration mode is enabled; or calibration processing is performed on a resistance control code in a full calibration mode if the last latched value and the initial default value of the resistance control code are the same when the short calibration mode is enabled; and latching processing is performed on the resistance control code after the calibration processing is completed. The resistance control code is configured to adjust resistance of a resistor unit.

In some embodiments, the resistance control code includes a pull-down control code, the pull-down control code is configured to adjust pull-down resistance of the resistor unit. The calibration processing includes pull-down calibration processing, and the pull-down calibration processing occupies two clock cycles. That calibration processing is performed on a resistance control code in a short calibration mode includes the steps as follows. A subtraction by one operation is performed on an internal bit of the pull-down control code if the pull-down resistance of the resistor unit is greater than standard resistance in the 1st clock cycle of pull-down calibration processing; and the subtraction by one operation continues to be performed on the internal bit of the pull-down control code if the pull-down resistance of the resistor unit is still greater than the standard resistance in the 2nd clock cycle of pull-down calibration processing. Alternatively, a subtraction by one operation is performed on an internal bit of the pull-down control code if the pull-down resistance of the resistor unit is greater than standard resistance in the 1st clock cycle of pull-down calibration processing; and an addition by one operation is performed on the internal bit of the pull-down control code if the pull-down resistance of the resistor unit is less than the standard resistance in the 2nd clock cycle of pull-down calibration processing. Alternatively, an addition by one operation is performed on an internal bit of the pull-down control code if the pull-down resistance of the resistor unit is less than standard resistance in the 1st clock cycle of pull-down calibration processing; and the addition by one operation continues to be performed on the internal bit of the pull-down control code if the pull-down resistance of the resistor unit is still less than the standard resistance in the 2nd clock cycle of pull-down calibration processing. Alternatively, an addition by one operation is performed on an internal bit of the pull-down control code if the pull-down resistance of the resistor unit is less than standard resistance in the 1st clock cycle of pull-down calibration processing; and a subtraction by one operation is performed on the internal bit of the pull-down control code if the pull-down resistance of the resistor unit is greater than the standard resistance in the 2nd clock cycle of pull-down calibration processing. The internal bit of the pull-down control code is a smallest bit of the pull-down control code, and the internal bit of the pull-down control code is not open to a user.

In some embodiments, the resistance control code further includes a pull-up control code, the pull-up control code is configured to adjust pull-up resistance of the resistor unit. The calibration processing further includes pull-up calibration processing, and the pull-up calibration processing occupies two clock cycles. That calibration processing is performed on a resistance control code in a short calibration mode further includes the steps as follows. A subtraction by one operation is performed on an internal bit of the pull-up control code if the pull-up resistance of the resistor unit is less than the standard resistance in the 1st clock cycle of pull-up calibration processing; and the subtraction by one operation continues to be performed on the internal bit of the pull-up control code if the pull-up resistance of the resistor unit is still less than the standard resistance in the 2nd clock cycle of pull-up calibration processing.

Alternatively, a subtraction by one operation is performed on an internal bit of the pull-up control code if the pull-up resistance of the resistor unit is less than the standard resistance in the 1 st clock cycle of pull-up calibration processing; and an addition by one operation is performed on the internal bit of the pull-up control code if the pull-up resistance of the resistor unit is greater than the standard resistance in the 2nd clock cycle of pull-up calibration processing. Alternatively, an addition by one operation is performed on an internal bit of the pull-up control code if the pull-up resistance of the resistor unit is greater than the standard resistance in the 1st clock cycle of pull-up calibration processing; and the addition by one operation continues to be performed on the internal bit of the pull-up control code if the pull-up resistance of the resistor unit is greater than the standard resistance in the 2nd clock cycle of pull-up calibration processing. Alternatively, an addition by one operation is performed on an internal bit of the pull-up control code if the pull-up resistance of the resistor unit is greater than the standard resistance in the 1st clock cycle of pull-up calibration processing; and a subtraction by one operation is performed on the internal bit of the pull-up control code if the pull-up resistance of the resistor unit is less than the standard resistance in the 2nd clock cycle of pull-up calibration processing. The internal bit of the pull-up control code is a smallest bit of the pull-up control code, and the internal bit of the pull-up control code is not open to the user.

### BRIEF DESCRIPTION OF DRAWINGS

FIG. 1 is a schematic diagram of a circuit structure of pull-up calibration processing;

FIG. 2 is a schematic diagram of a circuit structure of pull-down calibration processing;

FIG. 3 is a schematic diagram of a structure of a resistance calibration circuit according to an embodiment of the present disclosure;

FIG. 4 is a schematic diagram of a structure of another resistance calibration circuit according to an embodiment of the present disclosure;

FIG. 5 is a schematic diagram of calibration processing steps according to an embodiment of the present disclosure;

FIG. 6 is a schematic diagram of a specific structure of a calibration circuit according to an embodiment of the present disclosure;

FIG. 7 is a schematic diagram of a signal waveform according to an embodiment of the present disclosure;

FIG. 8 is a specific schematic flowchart 1 of calibration processing according to an embodiment of the present disclosure;

FIG. 9 is a specific schematic flowchart 2 of calibration processing according to an embodiment of the present disclosure;

FIG. 10 is a schematic flowchart of a resistance calibration method according to an embodiment of the present disclosure; and

FIG. 11 is a schematic diagram of a structure of a memory according to an embodiment of the present disclosure.

### DESCRIPTION OF EMBODIMENTS

The technical solutions in the embodiments of the present disclosure are clearly described below with reference to the accompanying drawings in the embodiments of the present disclosure. It may be understood that a specific embodiment described herein is merely intended to explain the related application, but is not intended to limit this application. In addition, it should be further noted that for ease of description, only a part related to the related application is shown in the accompanying drawings.

Unless otherwise defined, all technical and scientific terms utilized in this specification have meanings the same as those commonly understood by a person skilled in the technical field of the present disclosure. The terms utilized in this specification are merely intended to describe the embodiments of the present disclosure, but are not intended to limit the present disclosure.

The following descriptions relate to “some embodiments” describing a subset of all possible embodiments. However, it may be understood that “some embodiments” may be the same subset or different subsets of all the possible embodiments, and may be combined with each other when there is no conflict.

It should be noted that the term “first\second\third” in the embodiments of the present disclosure is merely intended to distinguish between similar objects, and does not represent specific sorting for the objects. It may be understood that “first\second\third” may be interchanged for a specific sequence or order if allowed, so that the embodiments of the present disclosure described herein can be implemented in a sequence other than those shown or described herein.

The following are nouns and abbreviations related to the embodiments of the present disclosure:
dynamic random access memory (DRAM);
synchronous dynamic random access memory (SDRAM);
double data rate SDRAM (DDR SDRAM);
low power DDR (LPDDR); and
5th LPDDR (LPDDR5).

An output driver circuit configured to perform output driving and signal termination exists in a memory, and resistance of equivalent resistance of the output driver circuit needs to be calibrated to match an actual application scenario. Specifically, in a calibration process, the resistance of the equivalent resistance of the output driver circuit needs to be changed by adjusting a value of a resistance control code, until the resistance of the equivalent resistance of the output driver circuit meets a requirement. The foregoing process is ZQ calibration.

ZQ calibration includes calibration of pull-down resistance (also referred to as pull-down calibration processing) and calibration of pull-up resistance (also referred to as pull-up calibration processing). ZQ control codes specifically include a pull-up control code Zqpu and a pull-down control code Zqpd.

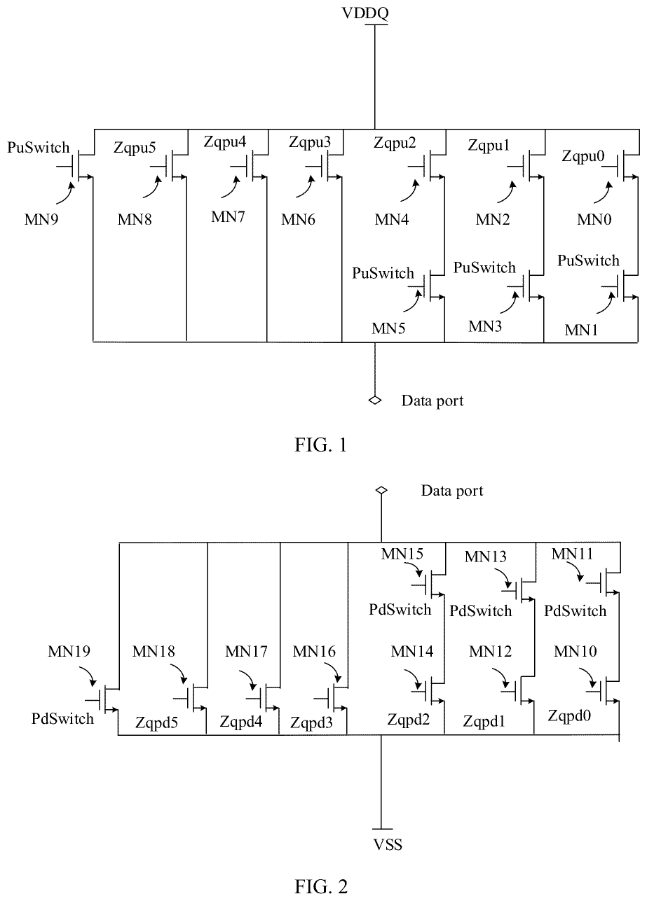

For pull-up calibration, as shown in FIG. 1, for a pull-up resistance part, resistance of the output driver circuit is controlled by six adjustable signals (Zqpu0 to Zqpu5), namely, a pull-up control code Zqpu[5:0]. However, an internal bit Zqpu0 is not open to a user, and only five bits in the pull-up control code are finally latched, and are specifically Zqpu[5:1]. In addition, in FIG. 1, VDDQ denotes a power signal, and PuSwitch denotes a pull-up switch signal. All pull-up switch signals PuSwitch are utilized to turn on controlled switching transistors in a pull-up calibration process. In addition, sizes of different switching transistors in FIG. 1 may be different. For example, the sizes of all the switching transistors may be designed based on the proportion as follows: switching transistor MN0: switching transistor MN1: switching transistor MN2: switching transistor MN3: switching transistor MN4: switching transistor MN5: switching transistor MN6: switching transistor MN7: switching transistor MN8: switching transistor MN9=1:1:2:2:4:4:4:8:16:16.

For pull-down calibration, as shown in FIG. 2, for a pull-down resistance part, resistance of the output driver circuit is also controlled by six adjustable signals (Zqpd0 to Zqpd5), namely, a pull-down control code Zqpd[5:0]. However, an internal bit Zqpd0 is not open to the user. In addition, in FIG. 2, VSS denotes a ground signal, and PdSwitch denotes a pull-down switch signal. All pull-down switch signals PdSwitch are utilized to turn on controlled switching transistors in a pull-down calibration process. Similarly, sizes of different switching transistors (MN10 to MN19) in FIG. 2 may be different.

Two ZQ calibration modes are available for selection in LPDDR5: a command calibration mode and a background calibration mode. In the background calibration mode, timing is performed by a timer inside a DRAM, and ZQ calibration is performed again at a fixed time interval. Currently, ZQ calibration is performed in a dichotomization-based full calibration mode in the background calibration mode.

The pull-up calibration processing is taken as an example. The pull-up control code Zqpu[5:0]=000000 is utilized as a calibration start point in the full calibration mode. The steps as follows are mainly included.

In step 1, Zqpu[5]=1 is set, and whether pull-up equivalent resistance of the output driver circuit is greater than standard resistance is determined.

In step 2, Zqpu[5]=1 is determined, and Zqpu[4]=1 is set, if the pull-up equivalent resistance of the output driver circuit is greater than the standard resistance; or Zqpu[5]=0 is determined, and Zqpu[4]=1 is set, if the pull-up equivalent resistance of the output driver circuit is less than the standard resistance; and whether the pull-up equivalent resistance of the output driver circuit is greater than the standard resistance is determined again.

Step 3 to step 7 are all similar to step 2.

In other words, a value of Zqpu[5] can be determined in step 2, a value of Zqpu[4] can be determined in step 3, a value of Zqpu[3] can be determined in step 4, a value of Zqpu[2] can be determined in step 5, a value of Zqpu[1] can be determined in step 6, and a value of Zqpu[0] can be determined in step 7. Each of the foregoing steps occupies one clock cycle. Therefore, a total of seven clock cycles need to be occupied. Similarly, pull-down calibration processing also needs to occupy seven clock cycles. Consequently, ZQ calibration has relatively large power consumption, and occupies a large quantity of clock cycles.

The embodiments of the present disclosure are described below in detail with reference to the accompanying drawings.

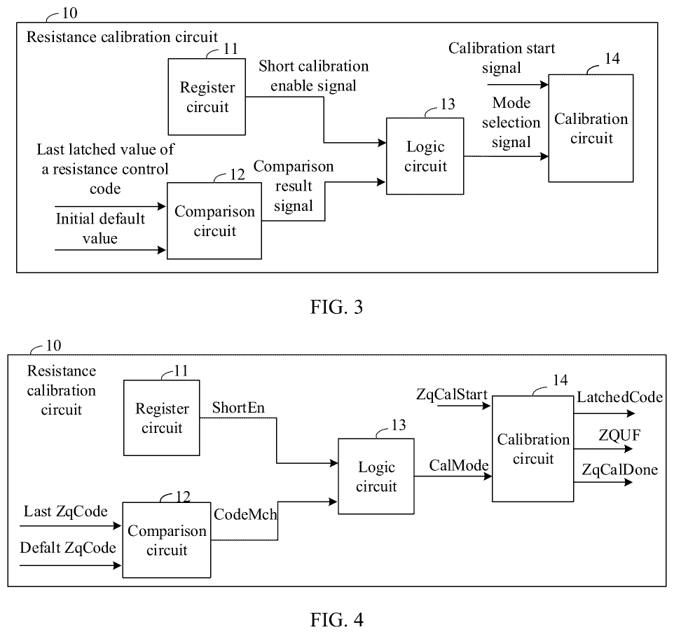

In an embodiment of the present disclosure, FIG. 3 is a schematic diagram of structural composition of a resistance calibration circuit 10 according to an embodiment of the present disclosure. As shown in FIG. 3, the resistance calibration circuit 10 includes:
a register circuit 11, configured to store and output a short calibration enable signal;
a comparison circuit 12, configured to: receive a last latched value and an initial default value of a resistance control code, perform a consistency comparison between the last latched value and the initial default value of the resistance control code, and output a comparison result signal;
a logic circuit 13, configured to: receive the short calibration enable signal and the comparison result signal, perform a logical operation on the short calibration enable signal and the comparison result signal, and output a mode selection signal; and
a calibration circuit 14, configured to: perform calibration processing on the resistance control code in one of a short calibration mode and a full calibration mode based on the mode selection signal when a calibration start signal is received, and perform latching processing on the resistance control code after calibration processing is completed.

Both the register circuit 11 and the comparison circuit 12 are connected to the logic circuit 13, and the logic circuit 13 is connected to the calibration circuit 14.

It should be noted that, as described above, equivalent resistance of an output driver circuit may be offset due to a change of an environment parameter (e.g., a voltage/temperature). Therefore, the resistance control code needs to be periodically calibrated. However, there is relatively high power consumption and a relatively large quantity of occupied clock cycles in a resistance calibration process in the full calibration mode. To resolve this problem, this embodiment of the present disclosure provides the resistance calibration circuit 10 to calibrate the resistance of the output driver circuit. A short calibration mode is further introduced based on the full calibration mode for the resistance calibration circuit 10. In particular, energy consumption in the short calibration mode is less than energy consumption in the full calibration mode, and/or a quantity of clock cycles occupied in the short calibration mode is less than a quantity of clock cycles occupied in the full calibration mode. In this way, in some scenarios, calibration processing is performed in the short calibration mode instead of the full calibration mode, to reduce power consumption, and reduce resource occupation.

It should be further noted that in this embodiment of the present disclosure, a level value of the short calibration enable signal is set, to control a specific mode in which the resistance calibration circuit 10 performs calibration. However, it should be noted that incomplete calibration is essentially performed in the short calibration mode, and the first time of calibration after a memory is powered on (or initialized) needs to be performed in the full calibration mode. Therefore, as shown in FIG. 3, if the comparison result signal indicates that the last latched value and the initial default value of the resistance control code are consistent, it indicates that current calibration is the first time of calibration after the memory is powered on (or initialized), and calibration needs to be performed in the full calibration mode; or if the comparison result signal indicates that the last latched value and the initial default value of the resistance control code are inconsistent, calibration is performed in one of the short calibration mode and the full calibration mode based on the short calibration enable signal.

In this way, the resistance calibration circuit 10 provided in this embodiment of the present disclosure can execute a process of the first time of calibration after a memory is powered on (or initialized) in the full calibration mode, and subsequently execute a calibration process in one of the short calibration mode and the full calibration mode based on the short calibration enable signal, to reduce energy consumption of resistance calibration, and ensure calibration correctness.

It should be noted that the register circuit 11 may be specifically a mode register, and the short calibration enable signal occupies one parameter bit. The comparison circuit 12 may include an XOR gate, an XNOR gate, and the like. The logic circuit 13 may include but is not limited to the components as follows: a NAND gate, a NOR gate, an AND gate, an OR gate, and a NOT gate. For specific composition of the calibration circuit 14, refer to subsequent descriptions.

As shown in FIG. 4, the last latched value of the resistance control code may be denoted as last ZqCode, the initial default value may be denoted as Defalt ZqCode, the comparison result signal may be denoted as CodeMch, the short calibration enable signal may be denoted as ShortEn, the mode selection signal may be denoted as CalMode, and the calibration start signal may be denoted as ZqCalStart.

In some embodiments, as shown in FIG. 3 and FIG. 4, the comparison circuit 12 is specifically configured to: output the comparison result signal CodeMch in a first state when the last latched value last ZqCode and the initial default value Defalt ZqCode of the resistance control code are different; or output the comparison result signal CodeMch in a second state when the last latched value last ZqCode and the initial default value Defalt ZqCode of the resistance control code are the same. A logic potential in the first state is different from a logic potential in the second state. Details may be determined based on an actual application scenario.

Correspondingly, as shown in FIG. 3 and FIG. 4, the logic circuit 13 is specifically configured to: output the mode selection signal CalMode in a fifth state when the short calibration enable signal ShortEn is in a fourth state; or output the mode selection signal CalMode in a sixth state when the short calibration enable signal ShortEn is in a third state and the comparison result signal CodeMch is in the first state; or output the mode selection signal CalMode in a fifth state when the short calibration enable signal ShortEn is in a third state and the comparison result signal CodeMch is in the second state.

Herein, a logic potential in the third state is different from a logic potential in the fourth state, the short calibration enable signal ShortEn in the third state indicates to enable the short calibration mode, the short calibration enable signal ShortEn in the fourth state indicates to disable the short calibration mode, and a logic potential in the fifth state is different from a logic potential in the sixth state. Details may be determined based on an actual application scenario.

It should be noted that, in one case, the level value of the short calibration enable signal ShortEn may be set by a user. In another case, the level value of the short calibration enable signal ShortEn may alternatively be determined through another mechanism in the circuit. For example, because the equivalent resistance of the output driver circuit is mainly affected by the environment parameter (voltage/temperature), the short calibration enable signal ShortEn may be controlled to be in the third state if a change of the environment parameter is relatively small; or the short calibration enable signal ShortEn may be controlled to be in the fourth state if a change of the environment parameter is relatively large. In addition, an initialization operation may alternatively be performed if the change of the environment parameter is relatively large, so that a value of the resistance control code is the default initial value. In this way, the resistance calibration circuit 10 can still perform calibration in the full calibration mode, to ensure calibration correctness.

In other words, calibration does not need to be performed in the full calibration mode when the voltage and the temperature do not suddenly change. However, in this embodiment of the present disclosure, a short calibration mode-based calibration mechanism is proposed for such a case in which calibration does not need to be performed in the full calibration mode, to reduce ZQ calibration time and calibration power consumption.

Correspondingly, as shown in FIG. 3 and FIG. 4, the calibration circuit 14 is specifically configured to: when the calibration start signal ZqCalStart is received, perform calibration processing on the resistance control code in the full calibration mode if the mode selection signal CalMode is in the fifth state, or perform calibration processing on the resistance control code in the short calibration mode if the mode selection signal CalMode is in the sixth state.

The calibration circuit 14 is further configured to output a new latched value LatchedCode of the resistance control code, a change recording signal ZQUE, and a calibration end signal ZqCalDone after calibration processing is ended. The change recording signal ZQUE indicates whether the latched value of the resistance control code changes.

Herein, the change recording signal ZQUF is in a ninth level state if the new latched value LatchedCode of the resistance control code changes relative to the last latched value last ZqCode; or the change recording signal ZQUF is in a tenth level state if the new latched value LatchedCode of the resistance control code does not change relative to the last latched value last ZqCode. A logic potential in the ninth level state is different from a logic potential in the tenth level state.

It should be noted that, in a first optional scenario, the first state, the third state, and the fifth state are high level states “1”, the second state, the fourth state, and the sixth state are low level states “0”, and the logic circuit 13 is mainly a NAND gate. Two input terminals of the NAND gate respectively receive the short calibration enable signal ShortEn and the comparison result signal CodeMch, and an output terminal of the NAND gate outputs the mode selection signal CalMode. In this case, the signals have the several changes as follows.

(1) The short calibration enable signal ShortEn is set to 1, and the comparison result signal CodeMch=1 (the last latched value last ZqCode and the initial default value Defalt ZqCode of the resistance control code are inconsistent). In this case, the mode selection signal CalMode=0, and the calibration circuit 14 performs calibration processing in the short calibration mode.

(2) The short calibration enable signal ShortEn is set to 1, and the comparison result signal CodeMch=0 (the last latched value last ZqCode and the initial default value Defalt ZqCode of the resistance control code are consistent). In this case, the mode selection signal CalMode=1, and the calibration circuit 14 performs calibration processing in the full calibration mode.

(3) The short calibration enable signal ShortEn is set to 0. The mode selection signal CalMode=1 regardless of a specific state of the comparison result signal CodeMch. In this case, the calibration circuit 14 performs calibration processing in the full calibration mode.

In a second optional scenario, in a second optional scenario, the first state, the third state, and the fifth state are low level states “0”, the second state, the fourth state, and the sixth state are high level states “1”, and the logic circuit 13 is mainly a NOR gate. Two input terminals of the NOR gate respectively receive the short calibration enable signal ShortEn and the comparison result signal CodeMch, and an output terminal of the NOR gate outputs the mode selection signal CalMode.

There are more possibilities in this embodiment of the present disclosure in addition to the first optional scenario and the second optional scenario. The first optional scenario is taken as an example for explanation and description in subsequent embodiments, and another scenario may be adaptively understood.

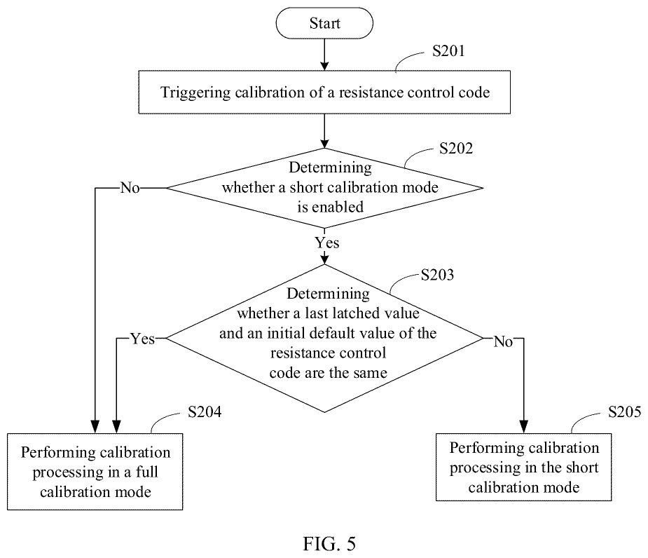

It can be learned from the foregoing descriptions that the resistance calibration circuit 10 may implement control logic shown in FIG. 5. The steps as follows are specifically included.

In the step of S201, calibration of the resistance control code is triggered.

In the step of S202, whether the short calibration mode is enabled is determined.

Herein, step S203 is performed if a determining result of step S202 is that the short calibration mode is enabled; or step S204 is performed if the determining result is that the short calibration mode is disabled.

It should be noted that “the short calibration mode is enabled” is reflected as “the short calibration enable signal ShortEn is in the third state” in the circuit, and “the short calibration mode is disabled” is reflected as “the short calibration enable signal ShortEn is in the fourth state” in the circuit.

In the step of S203, whether the last latched value and the initial default value of the resistance control code are the same is determined.

Herein, step S204 is performed if a determining result of step S203 is that the last latched value and the initial default value of the resistance control code are the same; or step S205 is performed if the determining result is that the last latched value and the initial default value of the resistance control code are different.

In the step of S204, calibration processing is performed in the full calibration mode.

In the step of S205, calibration processing is performed in the short calibration mode.

It can be learned from the foregoing descriptions that the register circuit 11 (namely, the MR) is configured to indicate enabling and disabling of the short calibration mode. Whether the last latched value last ZqCode and the initial default value Defalt ZqCode of the resistance control code are the same needs to be further considered when the short calibration mode is enabled. Specifically, if the last latched value last ZqCode and the initial default value of the resistance control code are the same, the mode selection signal CalMode is at a logic potential representing the full calibration mode; or if the last latched value last ZqCode and the initial default value Defalt ZqCode of the resistance control code are different, the mode selection signal CalMode is at a logic potential representing the short calibration mode. In other words, the last latched value last ZqCode and the initial default value Defalt ZqCode of the resistance control code are the same for the first time of calibration after power-on. Therefore, the full calibration mode is utilized for the first time of calibration by default. The last latched value last ZqCode and the initial default value Defalt ZqCode of the resistance control code are the same after resetting/initialization processing. Therefore, the full calibration mode is utilized for the first time of calibration by default, to ensure calibration correctness. In a subsequent calibration process, the short calibration mode is utilized if the short calibration enable signal is configured to indicate a logic potential of the short calibration mode, to reduce power consumption.

In a specific embodiment, regardless of the short calibration mode or the full calibration mode, calibration processing includes pull-up calibration processing and pull-down calibration processing, the initial default value Defalt ZqCode includes a pull-up default value and a pull-down default value, and the resistance control code may be denoted as Zqcode, and specifically includes a pull-up control code Zqpu[5:0] and a pull-down control code Zqpd[5:0]. Herein, pull-up calibration processing is calibrating the pull-up control code Zqpu[5:0], pull-down calibration processing is calibrating the pull-down control code Zqpd[5:0], and pull-up calibration processing and pull-down calibration processing are separately performed. In particular, latched values of the resistance control code are Zqpu[5:1] and Zqpd[5:1]. An internal bit Zqpu[0] and an internal bit Zqpd[0] are only utilized for a calibration process but are not latched, or are not open to the user.

In different application scenarios, “the last latched value last ZqCode and the initial default value Defalt ZqCode of the resistance control code are the same” may have one of the meanings as follows. (1) A last latched value of the pull-up control code is the same as the pull-up default value. (2) A last latched value of the pull-down control code is the same as the pull-down default value. (3) A last latched value of the pull-up control code is the same as the pull-up default value, and a last latched value of the pull-down control code is the same as the pull-down default value.

It should be noted that there are multiple possible specific calibration logic of the short calibration mode. A structure of the calibration circuit 14 needs to be designed based on the calibration logic of the short calibration mode. The following provides only an optional example.

In a specific embodiment, in the short calibration mode, a start point of pull-up calibration processing is the last latched value Zqpu[5:1] of the pull-up control code, and a start point of pull-down calibration processing is the last latched value Zqpd[5:1] of the pull-down control code; and in the full calibration mode, a start point of pull-up calibration processing is the pull-up default value, and a start point of pull-down calibration processing is the pull-down default value.

In this way, the pull-up control code and the pull-down control code have different initial values in different calibration modes, so that a smaller quantity of clock cycles are occupied and there is less power consumption in the short calibration mode.

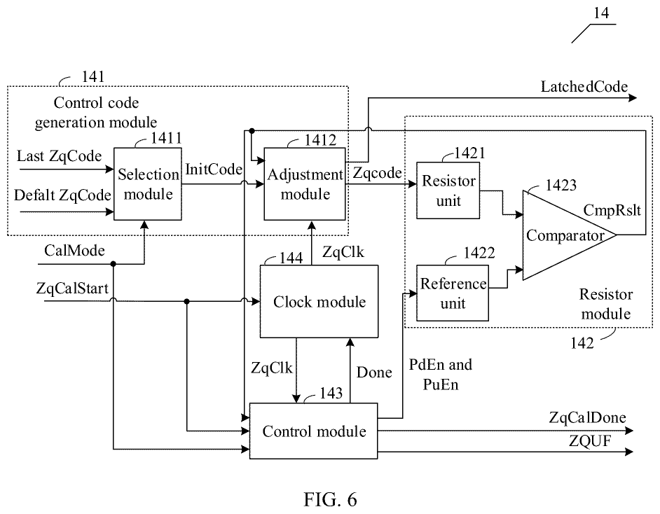

Correspondingly, as shown in FIG. 6, the calibration circuit 14 includes:
a control code generation module 141, configured to generate the pull-up control code and the pull-down control code based on the mode selection signal CalMode, the pull-up control code and the pull-down control code being collectively represented as Zqcode in FIG. 6;
a resistor module 142, including a resistor unit 1421, and configured to: control resistance of the resistor unit 1421 based on the pull-up control code and the pull-down control code, and generate and output a resistance comparison signal CmpRslt, the resistance comparison signal CmpRslt indicating a value relationship between the resistance of the resistor unit 1421 and standard resistance; and
a control module 143, configured to: determine, based on the resistance comparison signal CmpRslt, whether pull-up calibration processing or pull-down calibration processing is completed; and output the calibration end signal ZqCalDone and the change recording signal ZQUF after both pull-up calibration processing and pull-down calibration processing are completed.

The control code generation module 141 is further configured to: latch the resistance control code when a latch command signal is received, and generate a new latched value LatchedCode of the resistance control code.

As shown in FIG. 6, the control code generation module 141 is connected to the resistor module 142, and the resistor module 142 is connected to the control module 143.

It should be noted that a structure of the resistor unit 1421 in FIG. 6 is the same as a structure of the foregoing output driver circuit. As described above, pull-up calibration processing is specifically calibrating Zqpu[5:0], pull-down calibration processing is specifically calibrating Zqpd[5:0], and “latching the resistance control code” is latching Zqpu[5:1] and Zqpd[5:1].

It should be noted that the latch command signal is generated after both pull-up calibration processing and pull-down calibration processing are completed. In one case, it may be understood that the calibration start signal ZqCalStart and the latch command signal are sent by a memory controller to the DRAM, and a time interval between the calibration start signal ZqCalStart and the latch command signal is clearly greater than time required for pull-up calibration processing and pull-down calibration processing, to latch a calibrated resistance control code. In another case, the calibration start signal ZqCalStart is generated by the memory controller, and the latch command signal is generated based on the calibration end signal ZqCalDone.

It should be noted that because calibration start points of the pull-up control code and the pull-down control code are affected by a utilized calibration mode, the control code generation module 141 needs to work based on the mode selection signal CalMode. Specifically, as shown in FIG. 6, the control code generation module 141 includes:
a selection module 1411, configured to: receive the mode selection signal CalMode, the pull-up default value, the pull-down default value, the last latched value of the pull-up control code, and the last latched value of the pull-down control code; and output the pull-up default value as a pull-up initial value Zqpu₀[5:1], and output the pull-down default value as a pull-down initial value Zqpd₀[5:1], if the mode selection signal CalMode is in the fifth state; or output the last latched value of the pull-up control code as a pull-up initial value Zqpu₀[5:1], and output the last latched value of the pull-down control code as a pull-down initial value Zqpd₀[5:1], if the mode selection signal CalMode is in the sixth state; and
an adjustment module 1412, connected to the selection module 1411, and configured to: generate the pull-up control code Zqpu[5:0] and the pull-down control code Zqpd[5:0] based on the pull-up initial value Zqpu₀[5:1] and the pull-down initial value Zqpd₀[5:1]; adjust the pull-down control code Zqpd[5:0] in a process of pull-down calibration processing; and adjust the pull-up control code Zqpu[5:0] in a process of pull-up calibration processing.

In FIG. 6, the pull-up default value and the pull-down default value are collectively referred to as Defalt ZqCode, the last latched value of the pull-up control code and the last latched value of the pull-down control code are collectively referred to as last ZqCode, and the pull-up initial value Zqpu₀[5:1] and the pull-down initial value Zqpd₀[5:1] are collectively referred to as InitCode.

As described above, the adjustment module 1412 considers by default that an internal bit Zqpu₀=0 when the pull-up control code Zqpu[5:0] is generated based on the pull-up initial value Zqpu₀[5:1]; or the adjustment module 1412 considers by default that an internal bit Zqpd₀=0 when the pull-down control code Zqpd[5:0] is generated based on the pull-down initial value Zqpd₀[5:1], to implement bit padding processing.

In some embodiments, as shown in FIG. 6, the control module 143 is further configured to: receive the calibration start signal ZqCalStart, and output a pull-down enable signal pdEn and a pull-up enable signal PuEn based on the calibration start signal ZqCalStart. A valid pull-down enable signal pdEn indicates to perform pull-down calibration processing, a valid pull-up enable signal PuEn indicates to perform pull-up calibration processing, and a maximum of only one of the pull-down enable signal pdEn and the pull-up enable signal PuEn is valid.

The resistor module 142 further includes a reference unit 1422 and a comparator 1423.

The resistor unit 1421 is configured to: receive the pull-up control code Zqpu[5:0] and the pull-down control code Zqpd[5:0], and output a first voltage signal.

The reference unit 1422 is connected to the control module 143, and is configured to output a reference voltage signal based on the pull-down enable signal PdEn and the pull-up enable signal PuEn.

The comparator 1423 is connected to the resistor unit 1421 and the reference unit 1422, and is configured to: receive the first voltage signal and the reference voltage signal; and output the resistance comparison signal CmpRslt in a seventh state if the first voltage signal is greater than the reference voltage signal; or output the resistance comparison signal CmpRslt in an eighth state if the first voltage signal is not greater than the reference voltage signal.

In a possible case, the resistor unit 1421 may calibrate a pull-up resistance part through a standard resistor externally connected to the ground, and then calibrate a pull-down resistance part based on the calibrated pull-up resistance part, that is, perform pull-up calibration before pull-down calibration. In another possible case, the resistor unit 1421 may calibrate a pull-down resistance part through a standard resistor externally connected to a power supply, and then calibrate the pull-up resistance part based on the calibrated pull-down resistance part, that is, perform pull-down calibration before pull-up calibration.

In this way, a level state of the resistance comparison signal CmpRslt may indicate a relationship between standard resistance and pull-up equivalent resistance that is of the resistor unit 1421 and that is controlled based on the pull-up control code, to determine whether the current pull-up control code Zqpu[5:0] is proper; or a level state of the resistance comparison signal CmpRslt may indicate a relationship between standard resistance and pull-down equivalent resistance that is of the resistor unit 1421 and that is controlled based on the pull-down control code, to determine whether the current pull-down control code Zqpd[5:0] is proper.

In some embodiments, as shown in FIG. 6, the calibration circuit 14 further includes a clock module 144.

The clock module 144 is configured to output a calibration clock signal ZqClk based on the calibration start signal ZqCalStart.

The adjustment module 1412 is further configured to: receive the calibration clock signal ZqClk and the resistance comparison signal CmpRslt; perform addition or subtraction processing on the pull-up control code based on the resistance comparison signal CmpRslt in each clock cycle of the calibration clock signal ZqClk in the process of pull-up calibration processing; and perform addition or subtraction processing on the pull-down control code Zqpd[5:0] based on the resistance comparison signal CmpRslt in each clock cycle of the calibration clock signal ZqClk in the process of pull-down calibration processing.

The control module 143 is further configured to: record a change status of the resistance comparison signal CmpRslt in each clock cycle of the calibration clock signal ZqClk; determine that pull-down calibration is completed if a change of the resistance comparison signal CmpRslt meets a target end condition in the process of pull-down calibration processing; and determine that pull-up calibration is completed if a change of the resistance comparison signal CmpRslt meets a target end condition in the process of pull-up calibration processing. Both the control code generation module 141 and the control module 143 are connected to the clock module 144, and the control code generation module 141 is further connected to the resistor module 142.

It should be noted that “determine that pull-down calibration is completed” and “determine that pull-up calibration is completed” may be reflected as “outputting a corresponding signal” in the circuit, so that another module can learn of such information.

In some embodiments, the control module 143 is further configured to output an internal end signal Done after both pull-up calibration processing and pull-down calibration processing are completed; and the clock module 144 is further configured to: receive the internal end signal Done, and stop, based on the internal end signal Done, outputting the calibration clock signal ZqClk.

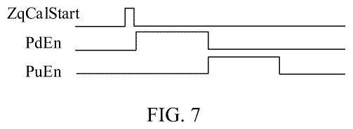

In this way, the calibration clock signal ZqClk output by the clock module 144 controls an entire calibration process. For example, pull-down calibration processing is performed before pull-up calibration processing. As shown in FIG. 7, the clock module 144 starts to output the calibration clock signal ZqClk, and the pull-down enable signal PdEn changes to a high level state (namely, becomes valid) when the calibration start signal ZqCalStart is received (which is reflected as generating one pulse for the calibration start signal ZqCalStart in FIG. 7). In this case, the adjustment module 1412 performs addition or subtraction on the pull-down control code Zqpd[5:0] based on the resistance comparison signal CmpRslt in each clock cycle of the calibration clock signal ZqClk until the pull-down control code Zqpd[5:0] is adjusted, that is, pull-down calibration processing is ended. Then, the pull-up enable signal PuEn changes to a high level state (namely, becomes valid). In this case, the adjustment module 1412 adjusts the pull-up control code Zqpu[5:0] based on the resistance comparison signal CmpRslt in each clock cycle of the calibration clock signal ZqClk until the pull-up control code Zqpu[5:0] is adjusted. In this case, pull-up calibration processing is ended, and the control module 143 outputs the calibration end signal ZqCalDone and the change recording signal ZQUF. Finally, the adjustment module 1412 further receives the latch command signal after a specific period of time, to perform latch processing on the pull-up control code Zqpu[5:1] and the pull-down control code Zqpd[5:1].

As described above, the change recording signal ZQUE is in a ninth state if the new latched value of the resistance control code changes relative to the last latched value (at least one of Zqpu[5:1] and Zqpd[5:1] changes); or the change recording signal ZQUF is in a tenth state if the new latched value of the resistance control code does not change relative to the last latched value (neither Zqpu[5:1] nor Zqpd[5:1] changes).

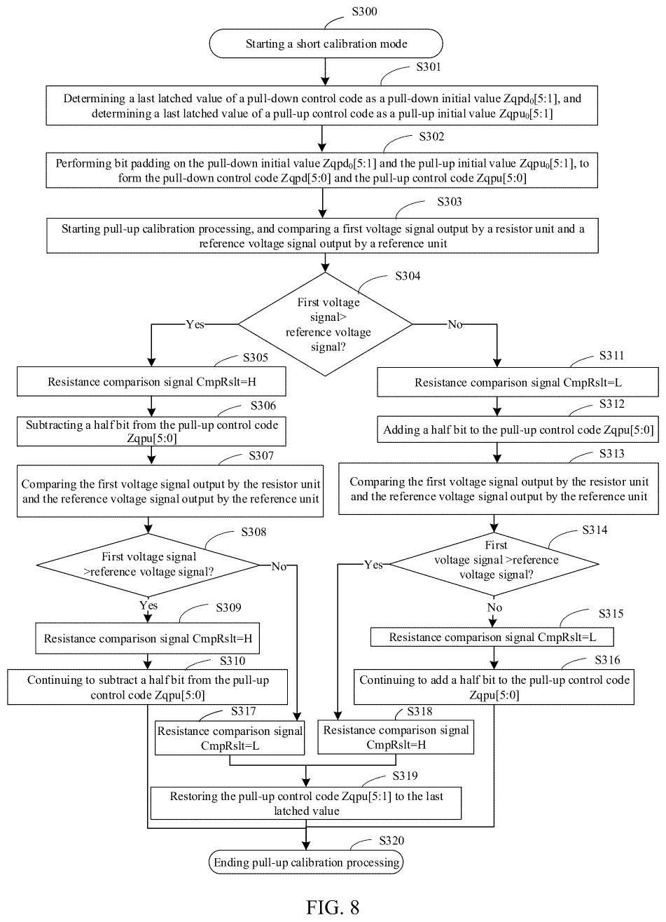

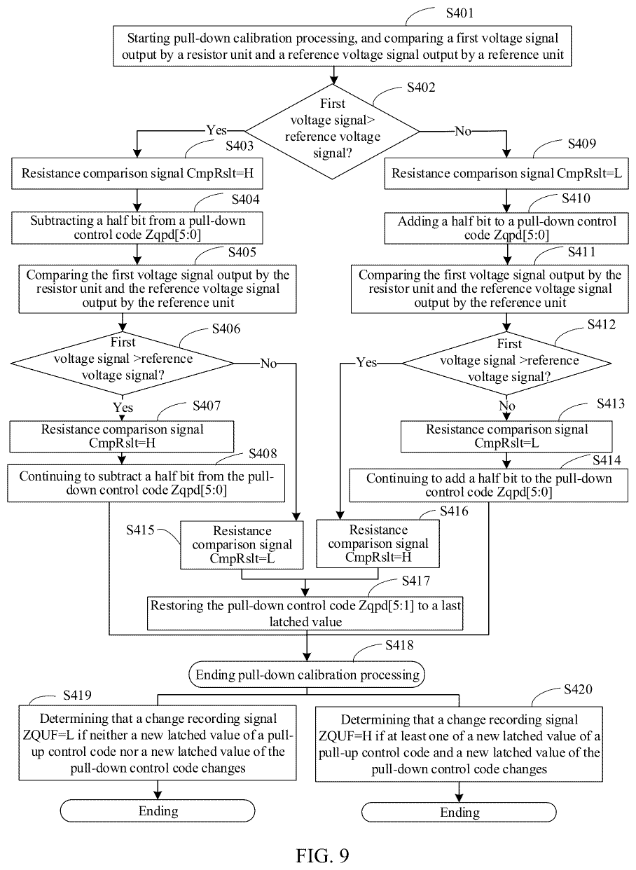

For a scenario in which pull-up calibration processing is performed before pull-down calibration processing, for example, both the seventh state and the ninth state are a high level state H, and both the eighth state and the tenth state are a low level state L. As shown in FIG. 8 and FIG. 9, the following provides specific step descriptions of the short calibration mode.

As shown in FIG. 8, a process in the short calibration mode includes the steps as follows.

In the step of S300, the short calibration mode is started.

In the step of S301, the last latched value of the pull-down control code is determined as the pull-down initial value Zqpd₀[5:1], and the last latched value of the pull-up control code is determined as the pull-up initial value Zqpu₀[5:1].

In the step of S302, bit padding is performed on the pull-down initial value Zqpd₀[5:1] and the pull-up initial value Zqpu₀[5:1], to form the pull-down control code Zqpd[5:0] and the pull-up control code Zqpu[5:0].

For example, the pull-down control code Zqpd[5:0]=10010_0 is formed through bit padding if the pull-down initial value Zqpd₀[5:1]=10010; and the pull-up control code Zqpu[5:0]=10010_0 is formed through bit padding if the pull-up initial value Zqpu₀[5:1]=10010.

In the step of S303, pull-up calibration processing is started, and the first voltage signal output by the resistor unit and the reference voltage signal output by the reference unit are compared.

In the step of S304, whether the first voltage signal is greater than the reference voltage signal is determined.

Herein, step S305 is performed if a determining result of step S304 is that the first voltage signal is greater than the reference voltage signal; or step S311 is performed if the determining result is that the first voltage signal is not greater than the reference voltage signal.

In the step of S305, the resistance comparison signal CmpRslt=H.

Herein, the obtained resistance comparison signal CmpRslt is in the high level state “H” because the first voltage signal is greater than the reference voltage signal.

In the step of S306, a half bit is subtracted from the pull-up control code Zqpu[5:0].

For example, Zqpu[5:0]=10010_0-00000_1=10001_1. In particular, a bit weight of Zqpu₀ is equivalent to a “half bit” of Zqpu[5:1] because the internal bit Zqpu₀ does not participate in latching processing. That is, a subtraction by one operation is performed on the internal bit Zqpu₀.

In the step of S307, the first voltage signal output by the resistor unit and the reference voltage signal output by the reference unit are compared.

In the step of S308, whether the first voltage signal is greater than the reference voltage signal is determined.

Herein, step S309 is performed if a determining result of step S308 is that the first voltage signal is greater than the reference voltage signal; or step S317 is performed if the determining result is that the first voltage signal is not greater than the reference voltage signal.

In the step of S309, the resistance comparison signal CmpRslt-H.

In the step of S310, a half bit continues to be subtracted from the pull-up control code Zqpu[5:0], and step S320 is performed.

In this case, Zqpu[5:0]=10001_1-00000_1=10001_0. That is, a subtraction by one operation continues to be performed on the internal bit Zqpu₀. In this case, Zqpu[5:1] has a total of one bit less than the last latched value, and pull-up calibration processing is completed.

In this case, the latched value Zqpu[5:1]-10001 of the pull-up control code changes relative to the last latched value when a subsequent latch command signal arrives.

In the step of S311, the resistance comparison signal CmpRslt-L.

Herein, the obtained resistance comparison signal CmpRslt is in the low level state “L” because the first voltage signal is less than the reference voltage signal.

In the step of S312, a half bit is added to the pull-up control code Zqpu[5:0].

In this case, Zqpu[5:0]=10010_0+00000_1=10010_1. That is, an addition by one operation is performed on the internal bit Zqpu₀.

In the step of S313, the first voltage signal output by the resistor unit and the reference voltage signal output by the reference unit are compared.

In the step of S314, whether the first voltage signal is greater than the reference voltage signal is determined.

Herein, step S318 is performed if a determining result of step S314 is that the first voltage signal is greater than the reference voltage signal; or step S315 is performed if the determining result is that the first voltage signal is not greater than the reference voltage signal.

In the step of S315, the resistance comparison signal CmpRslt=L.

In the step of S316, a half bit continues to be added to the pull-up control code Zqpu[5:0], and step S320 is performed.

In this case, Zqpu[5:0]=10010_1+00000_1=10011_0. That is, an addition by one operation is performed on the internal bit Zqpu₀. In this way, Zqpu[5:1] has a total of one bit more than the last latched value, and pull-up calibration processing is ended.

In this case, the latched value Zqpu[5:1]=10011 of the pull-up control code changes relative to the last latched value when a subsequent latch command signal arrives.

In the step of S317, the resistance comparison signal CmpRslt-L, and step S319 is performed.

In the step of S318, the resistance comparison signal CmpRslt-H, and step S319 is performed.

In the step of S319, the pull-up control code Zqpu[5:1] is restored to the last latched value.

Specifically, if S319 is performed after S317, a specific operation of S319 is as follows. A half bit is added to the pull-up control code. That is, Zqpu[5:0]=10001_1+00000_1=10010 0. If S319 is performed after S318, a specific operation of S319 is as follows. A half bit is subtracted from the pull-up control code. That is, Zqpu[5:0]=10010_1-00000_1=10010_0, and pull-up calibration processing is ended.

In this case, the pull-up control code Zqpu[5:1]=10010 does not change relative to the last latched value when a subsequent latch command signal arrives.

In the step of S320, pull-up calibration processing is ended.

In this way, pull-up calibration processing occupies two clock cycles.

As shown in FIG. 9, steps S401 to S420 continue to be performed after step S320, to complete a pull-down calibration part. Pull-down calibration processing specifically includes the steps as follows.

In the step of S401, pull-down calibration processing is started, and the first voltage signal output by the resistor unit and the reference voltage signal output by the reference unit are compared.

In the step of S402, whether the first voltage signal is greater than the reference voltage signal is determined.

Herein, step S403 is performed if a determining result of step S402 is that the first voltage signal is greater than the reference voltage signal; or step S409 is performed if the determining result is that the first voltage signal is not greater than the reference voltage signal.

In the step of S403, the resistance comparison signal CmpRslt=H.

In the step of S404, a half bit is subtracted from the pull-down control code Zqpd[5:0].

In this case, Zqpd[5:0]=10010_0-00000_1=10001_1. That is, a subtraction by one operation is performed on the internal bit Zqpd₀.

In the step of S405, the first voltage signal output by the resistor unit and the reference voltage signal output by the reference unit are compared.

In the step of S406, whether the first voltage signal is greater than the reference voltage signal is determined.

Herein, step S407 is performed if a determining result of step S406 is that the first voltage signal is greater than the reference voltage signal; or step S415 is performed if the determining result is that the first voltage signal is not greater than the reference voltage signal.

In the step of S407, the resistance comparison signal CmpRslt=H.

In the step of S408, a half bit continues to be subtracted from the pull-down control code Zqpd[5:0], and step S418 is performed.

In this case, Zqpd[5:0]=10001_1-00000_1=10001_0. That is, a subtraction by one operation is performed on the internal bit Zqpu₀. In this way, Zqpd[5:1] has a total of one bit less than the last latched value.

In this case, when a subsequent latch command signal arrives, a current latched value Zqpd[5:1]=10001 of the pull-down control code changes relative to the last latched value.

In the step of S409, the resistance comparison signal CmpRslt=L.

In the step of S410, a half bit is added to the pull-down control code Zqpd[5:0].

In this case, Zqpd[5:0]=10010_0+00000_1=10010_1. That is, an addition by one operation is performed on the internal bit Zqpu₀.

In the step of S411, the first voltage signal output by the resistor unit and the reference voltage signal output by the reference unit are compared.

In the step of S412, whether the first voltage signal is greater than the reference voltage signal is determined.

Herein, step S416 is performed if a determining result of step S412 is that the first voltage signal is greater than the reference voltage signal; or step S413 is performed if the determining result is that the first voltage signal is not greater than the reference voltage signal.

In the step of S413, the resistance comparison signal CmpRslt=L.

In the step of S414, a half bit continues to be added to the pull-down control code Zqpd[5:0], and step S418 is performed.

In this case, Zqpd[5:0]=10010_1+00000_1=10011_0. That is, an addition by one operation is performed on the internal bit Zqpu₀. In this way, Zqpd[5:1] has a total of one bit more than the last latched value.

In this case, the latched value Zqpd[5:1]=10011 of the pull-down control code changes relative to the last latched value when a subsequent latch command signal arrives.

In the step of S415, the resistance comparison signal CmpRslt-L, and step S417 is performed.

In the step of S416, the resistance comparison signal CmpRslt=H, and step S417 is performed.

In the step of S417, the pull-down control code Zqpd[5:1] is restored to the last latched value.

Specifically, if S417 is performed after S415, a specific operation of S417 is as follows. A half bit is added to the pull-down control code. That is, Zqpd[5:0]=10001_1+00000_1=10010 0. If S417 is performed after S416, a specific operation of S417 is as follows. A half bit is subtracted from the pull-down control code. That is, Zqpd[5:0]=10010_1-00000_1=10010 0.

In this case, the pull-down control code Zqpd[5:1]=10010 does not change relative to the last latched value when a subsequent latch command signal arrives.

In the step of S418, pull-down calibration processing is ended, and step S419 or step S420 is performed.

In the step of S419, it is determined that the change recording signal ZQUF=L if neither a new latched value of the pull-up control code nor a new latched value of the pull-down control code changes.

In the step of S420, it is determined that the change recording signal ZQUF=H if at least one of a new latched value of the pull-up control code and a new latched value of the pull-down control code changes.

It should be noted that, as shown in FIG. 1, the pull-up resistance part of the resistor unit includes an N-type field effect transistor (NMOS). However, the pull-down resistance part of the resistor unit needs to include a P-type field effect transistor, to conform to the foregoing calibration logic. Alternatively, in some other embodiments, as shown in FIG. 2, the pull-down resistance part of the resistor unit may alternatively include an N-type field effect transistor. In this case, step S404 needs to be adjusted to “a half bit is added to the pull-down control code Zqpd[5:0]”, step S408 needs to be adjusted to “a half bit continues to be added to the pull-down control code Zqpd[5:0]”, step S410 needs to be adjusted to “a half bit is subtracted from the pull-down control code Zqpd[5:0]”, and step S414 needs to be adjusted to “a half bit continues to be subtracted from the pull-down control code Zqpd[5:0]”. Alternatively, the foregoing steps may not be modified, and the foregoing logic is implemented by introducing an inverter into the circuit.

It can be learned from the foregoing descriptions that a calibration process in the full calibration mode is different from a calibration process in the short calibration mode. At least (7×2) clock cycles are occupied in the full calibration mode, and at least (2×2) clock cycles are occupied in the short calibration mode. Therefore, at least (5×2) clock cycles can be reduced for each time of calibration processing in the short calibration mode. In this case, time and power consumption of ZQ calibration in each memory are clearly reduced because there may be many memories in one electronic device.

In addition, conditions for indicating that calibration is completed (including that pull-up calibration is completed and pull-down calibration is completed) in the full calibration mode and the short calibration mode are also different. Therefore, as shown in FIG. 6, the control module 143 is specifically configured to: receive the mode selection signal CalMode; and determine one of a preset full calibration end condition and a preset short calibration end condition as the target end condition based on the mode selection signal CalMode.

For example, in the short calibration mode, pull-up calibration processing and pull-down calibration processing each occupy two clock cycles, and the preset short calibration end condition includes the conditions as follows. (1) The resistance comparison signal CmpRslt is in the seventh state in the two clock cycles. (2) The resistance comparison signal CmpRslt is in the seventh state in the 1st clock cycle, and the resistance comparison signal CmpRslt is in the eighth state in the 2nd clock cycle. (3) The resistance comparison signal CmpRslt is in the eighth state in the two clock cycles. (4) The resistance comparison signal CmpRslt is in the eighth state in the 1st clock cycle, and the resistance comparison signal CmpRslt is in the seventh state in the 2nd clock cycle. There is “or” logic between the foregoing conditions. To be specific, for pull-up calibration processing, it may be considered that pull-up calibration is completed if any of the foregoing conditions is met; and for pull-down calibration processing, it is considered that pull-down calibration is completed if any of the foregoing conditions is met. In other words, in the two clock cycles, it is considered that pull-up calibration processing/pull-down calibration processing is completed regardless of a specific change of the resistance comparison signal CmpRslt. It should be understood that, resistance is usually not offset too much if a change of the temperature and the voltage is not large or a time interval between two times of calibration is relatively small. Therefore, the pull-up control code/pull-down control code usually does not need to change too much, and precision can be achieved through only fine adjustment.

In addition, in the full calibration mode, pull-up calibration processing and pull-down calibration processing each occupy seven clock cycles, and the preset full calibration end condition may be correspondingly set.

In the foregoing descriptions, whether calibration is ended needs to be determined based on the change status of the resistance comparison signal CmpRslt. Therefore, the target end condition essentially specifies the change of the resistance comparison signal CmpRslt. In some other embodiments, the target end condition may alternatively be determined based on a count of clock cycles because (7×2) clock cycles are occupied in the full calibration mode, and (2×2) clock cycles are occupied in the short calibration mode. To be specific, in the full calibration mode, a pull-down calibration process is ended after an interval of seven clock cycles after pull-down calibration processing is started; and a pull-up calibration process is ended after an interval of seven clock cycles after pull-up calibration processing is started. In the short calibration mode, a pull-down calibration process is ended after an interval of two clock cycles after pull-down calibration processing is started; and a pull-up calibration process is ended after an interval of two clock cycles after pull-up calibration processing is started.

To implement calibration steps shown in FIG. 9, when the mode selection signal is in the sixth state, the adjustment module 1412 is specifically configured to: (1) perform a subtraction by one operation on an internal bit of the pull-down control code if the resistance comparison signal CmpRslt is in the seventh state in the 1st clock cycle of pull-down calibration processing; and continue to perform the subtraction by one operation on the internal bit of the pull-down control code if the resistance comparison signal CmpRslt is still in the seventh state in the 2nd clock cycle of pull-down calibration processing; or (2) perform a subtraction by one operation on an internal bit of the pull-down control code if the resistance comparison signal CmpRslt is in the seventh state in the 1st clock cycle of pull-down calibration processing; and perform an addition by one operation on the internal bit of the pull-down control code if the resistance comparison signal CmpRslt is in the eighth state in the 2nd clock cycle of pull-down calibration processing; or (3) perform an addition by one operation on an internal bit of the pull-down control code if the resistance comparison signal CmpRslt is in the eighth state in the 1st clock cycle of pull-down calibration processing; and continue to perform the addition by one operation on the internal bit of the pull-down control code if the resistance comparison signal CmpRslt is still in the eighth state in the 2nd clock cycle of pull-down calibration processing; or (4) perform an addition by one operation on an internal bit of the pull-down control code if the resistance comparison signal CmpRslt is in the eighth state in the 1st clock cycle of pull-down calibration processing; and perform a subtraction by one operation on the internal bit of the pull-down control code if the resistance comparison signal CmpRslt is in the seventh state in the 2nd clock cycle of pull-down calibration processing.

Herein, the internal bit of the pull-down control code is a smallest bit of the pull-down control code, and the internal bit of the pull-down control code is not open to the user. In other words, “an addition by one operation on the internal bit” is equivalent to the foregoing “addition by a half bit operation”, and “a subtraction by one operation on the internal bit” is equivalent to the foregoing “subtraction by a half bit operation”.

To implement calibration steps shown in FIG. 8, when the mode selection signal is in the sixth state, the adjustment module 1412 is specifically configured to: (1) perform a subtraction by one operation on an internal bit of the pull-up control code if the resistance comparison signal CmpRslt is in the seventh state in the 1st clock cycle of pull-up calibration processing; and continue to perform the subtraction by one operation on the internal bit of the pull-up control code if the resistance comparison signal CmpRslt is still in the seventh state in the 2nd clock cycle of pull-up calibration processing; or (2) perform a subtraction by one operation on an internal bit of the pull-up control code if the resistance comparison signal CmpRslt is in the seventh state in the 1st clock cycle of pull-up calibration processing; and perform an addition by one operation on the internal bit of the pull-up control code if the resistance comparison signal CmpRslt is in the eighth state in the 2nd clock cycle of pull-up calibration processing; or (3) perform an addition by one operation on an internal bit of the pull-up control code if the resistance comparison signal CmpRslt is in the eighth state in the 1st clock cycle of pull-up calibration processing; and continue to perform the addition by one operation on the internal bit of the pull-up control code if the resistance comparison signal CmpRslt is still in the eighth state in the 2nd clock cycle of pull-up calibration processing; or (4) perform an addition by one operation on an internal bit of the pull-up control code if the resistance comparison signal CmpRslt is in the eighth state in the 1st clock cycle of pull-up calibration processing; and perform a subtraction by one operation on the internal bit of the pull-up control code if the resistance comparison signal CmpRslt is in the seventh state in the 2nd clock cycle of pull-up calibration processing.

Herein, the internal bit of the pull-up control code is a smallest bit of the pull-up control code, and the internal bit of the pull-up control code is not open to the user. In particular, the foregoing specific details of calibration are merely an example. Calibration details may be adjusted correspondingly based on an actual circuit design. For example, addition by one processing is changed to subtraction by one processing, and subtraction by one processing is changed to addition by one processing.

In conclusion, ZQ calibration does not need to be performed in the full calibration mode when the voltage and the temperature do not suddenly change. The present disclosure provides short calibration mode-based optimized ZQ calibration logic for this case, to reduce ZQ calibration time and calibration power consumption. Specifically, the short calibration mode may be enabled (that is, the short calibration enable signal is configured to be in the third state) in a background calibration mode, to reduce a large amount of calibration time and power consumption. In addition, the short calibration mode may be further applied to a command calibration mode.

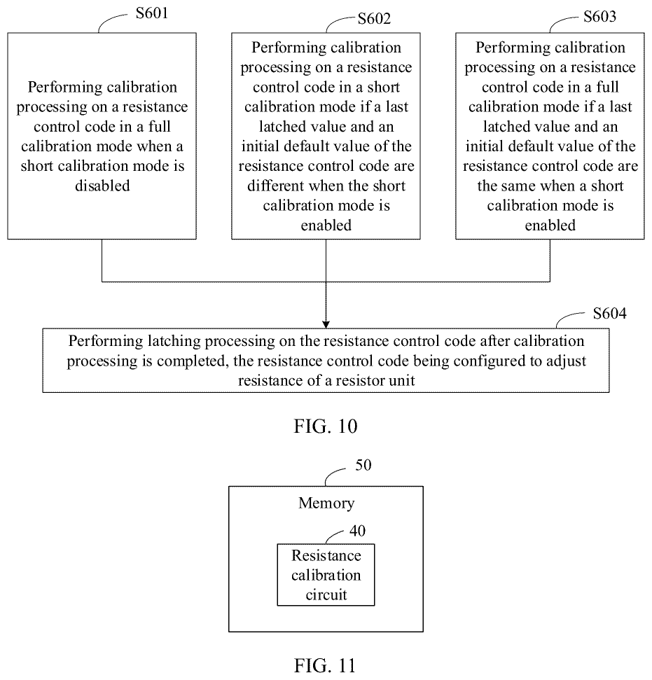

In another embodiment of the present disclosure, FIG. 10 shows a resistance calibration method according to an embodiment of the present disclosure. As shown in FIG. 10, the method includes the steps as follows.

In the step of S601, calibration processing is performed on a resistance control code in a full calibration mode when a short calibration mode is disabled.

In the step of S602, calibration processing is performed on a resistance control code in a short calibration mode if a last latched value and an initial default value of the resistance control code are different when the short calibration mode is enabled.

In the step of S603, calibration processing is performed on a resistance control code in a full calibration mode if a last latched value and an initial default value of the resistance control code are the same when a short calibration mode is enabled.

It should be noted that there is “or logic” between steps S601, S602, and S603.

In the step of S604, latching processing is performed on the resistance control code after calibration processing is completed. The resistance control code is configured to adjust resistance of a resistor unit.

Herein, the resistor unit may be an output driver circuit in a DRAM.

It should be noted that the resistance control code includes a pull-down control code, the pull-down control code is configured to adjust pull-down resistance of the resistor unit, the calibration processing includes pull-down calibration processing, and pull-down calibration processing occupies two clock cycles. In a specific embodiment, that calibration processing is performed on a resistance control code in a short calibration mode includes the steps as follows.

(1) A subtraction by one operation is performed on an internal bit of the pull-down control code if the pull-down resistance of the resistor unit is greater than standard resistance in the 1st clock cycle of pull-down calibration processing, and the subtraction by one operation continues to be performed on the internal bit of the pull-down control code if the pull-down resistance of the resistor unit is still greater than the standard resistance in the 2nd clock cycle of pull-down calibration processing; or (2) a subtraction by one operation is performed on an internal bit of the pull-down control code if the pull-down resistance of the resistor unit is greater than standard resistance in the 1st clock cycle of pull-down calibration processing, and an addition by one operation is performed on the internal bit of the pull-down control code if the pull-down resistance of the resistor unit is less than the standard resistance in the 2nd clock cycle of pull-down calibration processing; or (3) an addition by one operation is performed on an internal bit of the pull-down control code if the pull-down resistance of the resistor unit is less than standard resistance in the 1st clock cycle of pull-down calibration processing, and the addition by one operation continues to be performed on the internal bit of the pull-down control code if the pull-down resistance of the resistor unit is still less than the standard resistance in the 2nd clock cycle of pull-down calibration processing; or (4) an addition by one operation is performed on an internal bit of the pull-down control code if the pull-down resistance of the resistor unit is less than standard resistance in the 1st clock cycle of pull-down calibration processing, and a subtraction by one operation is performed on the internal bit of the pull-down control code if the pull-down resistance of the resistor unit is greater than the standard resistance in the 2nd clock cycle of pull-down calibration processing.

Herein, the internal bit of the pull-down control code is a smallest bit of the pull-down control code, and the internal bit of the pull-down control code is not open to the user.

It should be understood that the foregoing embodiment is applied to a scenario in which a pull-down resistance part includes a P-type field effect transistor. In some other embodiments, if the pull-down resistance part includes an N-type field effect transistor, an addition by one operation is performed on an internal bit of the pull-down control code if the pull-down resistance of the resistor unit is greater than standard resistance; and a subtraction by one operation is performed on the internal bit of the pull-down control code if the pull-down resistance of the resistor unit is less than the standard resistance.

It should be further noted that the resistance control code further includes a pull-up control code, the pull-up control code is configured to adjust pull-up resistance of the resistor unit, the calibration processing further includes pull-up calibration processing, and pull-up calibration processing occupies two clock cycles. In a specific embodiment, that calibration processing is performed on a resistance control code in a short calibration mode includes the steps as follows.

(1) A subtraction by one operation is performed on an internal bit of the pull-up control code if the pull-up resistance of the resistor unit is less than the standard resistance in the 1st clock cycle of pull-up calibration processing, and the subtraction by one operation continues to be performed on the internal bit of the pull-up control code if the pull-up resistance of the resistor unit is still less than the standard resistance in the 2nd clock cycle of pull-up calibration processing; or (2) a subtraction by one operation is performed on an internal bit of the pull-up control code if the pull-up resistance of the resistor unit is less than the standard resistance in the 1st clock cycle of pull-up calibration processing, and an addition by one operation is performed on the internal bit of the pull-up control code if the pull-up resistance of the resistor unit is greater than the standard resistance in the 2nd clock cycle of pull-up calibration processing; or (3) an addition by one operation is performed on an internal bit of the pull-up control code if the pull-up resistance of the resistor unit is greater than the standard resistance in the 1st clock cycle of pull-up calibration processing, and the addition by one operation continues to be performed on the internal bit of the pull-up control code if the pull-up resistance of the resistor unit is greater than the standard resistance in the 2nd clock cycle of pull-up calibration processing; or (4) an addition by one operation is performed on an internal bit of the pull-up control code if the pull-up resistance of the resistor unit is greater than the standard resistance in the 1st clock cycle of pull-up calibration processing, and a subtraction by one operation is performed on the internal bit of the pull-up control code if the pull-up resistance of the resistor unit is less than the standard resistance in the 2nd clock cycle of pull-up calibration processing. The internal bit of the pull-up control code is a smallest bit of the pull-up control code, and the internal bit of the pull-up control code is not open to the user.

It should be understood that the foregoing embodiment is applied to a scenario in which a pull-up resistance part includes an N-type field effect transistor. In some other embodiments, calibration details need to be adjusted with reference to the foregoing content if the pull-up resistance part includes a P-type field effect transistor.

In conclusion, in this embodiment of the present disclosure, the short calibration mode is further introduced based on the full calibration mode. In some scenarios, calibration processing is performed in the short calibration mode instead of the full calibration mode, to reduce power consumption, and reduce resource occupation.

In still another embodiment of the present disclosure, FIG. 11 is a schematic diagram of structural composition of a memory 40 according to an embodiment of the present disclosure. As shown in FIG. 11, the memory 40 includes the foregoing resistance calibration circuit 10.

The foregoing is merely preferred embodiments of the present disclosure, and is not intended to limit the protection scope of the present disclosure. It should be noted that in the present disclosure, the terms “include”, “comprise”, or any other variant thereof are intended to cover non-exclusive inclusion, so that a procedure, method, article, or apparatus that includes a series of elements includes not only those elements but also other elements that are not expressly listed, or further includes elements inherent to such a procedure, method, article, or apparatus. An element preceded by “includes a . . . ” does not, without more constraints, exclude the presence of additional identical elements in the procedure, method, article, or apparatus that includes the element. The sequence numbers of the foregoing embodiments of the present disclosure are merely for the purpose of description, and do not represent priorities of the embodiments. The methods disclosed in the several method embodiments provided in the present disclosure may be randomly combined when there is no conflict, to obtain new method embodiments. The features disclosed in the several product embodiments provided in the present disclosure may be randomly combined when there is no conflict, to obtain new product embodiments. The features disclosed in the several method or device embodiments provided in the present disclosure may be randomly combined when there is no conflict, to obtain new method embodiments or new device embodiments. The foregoing is merely specific implementations of the present disclosure, but is not intended to limit the protection scope of the present disclosure. Any variation or replacement readily figured out by a person skilled in the art within the technical scope disclosed in the present disclosure shall fall within the protection scope of the present disclosure.

What is claimed is:

1. A resistance calibration circuit, the resistance calibration circuit comprising:
a register circuit, configured to store and output a short calibration enable signal;
a comparison circuit, configured to: receive a last latched value and an initial default value of a resistance control code, perform a consistency comparison between the last latched value and the initial default value of the resistance control code, and output a comparison result signal;
a logic circuit, configured to: receive the short calibration enable signal and the comparison result signal, perform a logical operation on the short calibration enable signal and the comparison result signal, and output a mode selection signal;
a calibration circuit, configured to: perform calibration processing on the resistance control code in one of a short calibration mode and a full calibration mode based on the mode selection signal when a calibration start signal is received, and perform latching processing on the resistance control code after calibration processing is completed; and
both the register circuit and the comparison circuit being connected to the logic circuit, and the logic circuit being connected to the calibration circuit.

2. The resistance calibration circuit according to claim 1, wherein
the comparison circuit is specifically configured to: output the comparison result signal in a first state when the last latched value and the initial default value of the resistance control code are different; or output the comparison result signal in a second state when the last latched value and the initial default value of the resistance control code are the same, a logic potential in the first state being different from a logic potential in the second state.

3. The resistance calibration circuit according to claim 1, wherein
the logic circuit is configured to: output the mode selection signal in a fifth state when the short calibration enable signal is in a fourth state; or output the mode selection signal in a sixth state when the short calibration enable signal is in a third state and the comparison result signal is in a first state; or output the mode selection signal in a fifth state when the short calibration enable signal is in a third state and the comparison result signal is in the second state; and
a logic potential in the third state is different from a logic potential in the fourth state, the short calibration enable signal in the third state indicates to enable the short calibration mode, the short calibration enable signal in the fourth state indicates to disable the short calibration mode, and a logic potential in the fifth state is different from a logic potential in the sixth state.

4. The resistance calibration circuit according to claim 3, wherein
the calibration circuit is specifically configured to: when the calibration start signal is received, perform calibration processing on the resistance control code in the full calibration mode if the mode selection signal is in the fifth state, or perform calibration processing on the resistance control code in the short calibration mode if the mode selection signal is in the sixth state; and
output a new latched value of the resistance control code, a change recording signal, and a calibration end signal after calibration processing is ended, the change recording signal indicating whether the latched value of the resistance control code changes.

5. The resistance calibration circuit according to claim 4, wherein the resistance control code comprises a pull-up control code and a pull-down control code, the initial default value comprises a pull-up default value and a pull-down default value, and the calibration processing comprises pull-up calibration processing and pull-down calibration processing;
in the short calibration mode, a start point of the pull-up calibration processing is a last latched value of the pull-up control code, and a start point of the pull-down calibration processing is a last latched value of the pull-down control code; and
in the full calibration mode, a start point of the pull-up calibration processing is the pull-up default value, and a start point of the pull-down calibration processing is the pull-down default value.

6. The resistance calibration circuit according to claim 5, wherein the calibration circuit comprises:
a control code generation module, configured to generate the pull-up control code and the pull-down control code based on the mode selection signal;
a resistor module, comprising a resistor unit, and configured to: control resistance of the resistor unit based on the pull-up control code and the pull-down control code, and generate and output a resistance comparison signal, the resistance comparison signal indicating a value relationship between the resistance of the resistor unit and standard resistance; and
a control module, configured to: determine, based on the resistance comparison signal, whether pull-up calibration processing or pull-down calibration processing is completed; and output the calibration end signal and the change recording signal after both pull-up calibration processing and pull-down calibration processing are completed;
the control code generation module is further configured to: latch the resistance control code when a latch command signal is received, and generate a new latched value of the resistance control code, the latch command signal being generated after both the pull-up calibration processing and the pull-down calibration processing are completed; and
the control code generation module is connected to the resistor module, and the resistor module is connected to the control module.

7. The resistance calibration circuit according to claim 6, wherein the control code generation module comprises:
a selection module, configured to: receive the mode selection signal, the pull-up default value, the pull-down default value, the last latched value of the pull-up control code, and the last latched value of the pull-down control code; and output the pull-up default value as a pull-up initial value, and output the pull-down default value as a pull-down initial value, if the mode selection signal is in the fifth state; or output the last latched value of the pull-up control code as a pull-up initial value, and output the last latched value of the pull-down control code as a pull-down initial value, if the mode selection signal is in a sixth state; and
an adjustment module, connected to the selection module, and configured to: generate the pull-up control code and the pull-down control code based on the pull-up initial value and the pull-down initial value; adjust the pull-down control code in a process of the pull-down calibration processing; and adjust the pull-up control code in a process of the pull-up calibration processing.

8. The resistance calibration circuit according to claim 7, wherein
the control module is further configured to: receive the calibration start signal, and output a pull-down enable signal and a pull-up enable signal based on the calibration start signal, a valid pull-down enable signal indicating to perform pull-down calibration processing, a valid pull-up enable signal indicating to perform pull-up calibration processing, and a maximum of only one of the pull-down enable signal and the pull-up enable signal being valid;
the resistor module further comprises a reference unit and a comparator;
the resistor unit is configured to: receive the pull-up control code and the pull-down control code, and output a first voltage signal;
the reference unit is connected to the control module, and is configured to output a reference voltage signal based on the pull-down enable signal and the pull-up enable signal; and
the comparator is connected to the resistor unit and the reference unit, and is configured to: receive the first voltage signal and the reference voltage signal; and output the resistance comparison signal in a seventh state if the first voltage signal is greater than the reference voltage signal; or output the resistance comparison signal in an eighth state if the first voltage signal is not greater than the reference voltage signal, a logic potential in the seventh state being different from a logic potential in the eighth state.

9. The resistance calibration circuit according to claim 7, wherein the calibration circuit further comprises a clock module;
the clock module is configured to output a calibration clock signal based on the calibration start signal;
the adjustment module is further configured to: receive the calibration clock signal and the resistance comparison signal; perform addition or subtraction processing on the pull-up control code based on the resistance comparison signal in each clock cycle of the calibration clock signal in the process of the pull-up calibration processing; and perform addition or subtraction processing on the pull-down control code based on the resistance comparison signal in each clock cycle of the calibration clock signal in the process of the pull-down calibration processing;
the control module is further configured to: record a change status of the resistance comparison signal in each clock cycle of the calibration clock signal; determine that pull-down calibration is completed if a change of the resistance comparison signal meets a target end condition in the process of the pull-down calibration processing; and determine that pull-up calibration is completed if a change of the resistance comparison signal meets a target end condition in the process of the pull-up calibration processing; and
both the control code generation module and the control module are connected to the clock module, and the control code generation module is further connected to the resistor module.

10. The resistance calibration circuit according to claim 9, wherein
the control module is further configured to output an internal end signal after both the pull-up calibration processing and the pull-down calibration processing are completed; and
the clock module is further configured to: receive the internal end signal, and stop, based on the internal end signal, outputting the calibration clock signal.

11. The resistance calibration circuit according to claim 9, wherein
the control module is specifically configured to: receive the mode selection signal; and determine one of a preset full calibration end condition and a preset short calibration end condition as the target end condition based on the mode selection signal.

12. The resistance calibration circuit according to any one of claim 8, wherein in the short calibration mode, the pull-down calibration processing occupies two clock cycles; and correspondingly, when the mode selection signal is in a sixth state:
the adjustment module is specifically configured to: perform a subtraction by one operation on an internal bit of the pull-down control code if the resistance comparison signal is in the seventh state in a 1st clock cycle of pull-down calibration processing, and continue to perform the subtraction by one operation on the internal bit of the pull-down control code if the resistance comparison signal is still in the seventh state in a 2nd clock cycle of pull-down calibration processing; or
perform a subtraction by one operation on an internal bit of the pull-down control code if the resistance comparison signal is in the seventh state in a 1st clock cycle of pull-down calibration processing, and perform an addition by one operation on the internal bit of the pull-down control code if the resistance comparison signal is in the eighth state in a 2nd clock cycle of pull-down calibration processing; or
perform an addition by one operation on an internal bit of the pull-down control code if the resistance comparison signal is in the eighth state in a 1st clock cycle of pull-down calibration processing, and continue to perform the addition by one operation on the internal bit of the pull-down control code if the resistance comparison signal is still in the eighth state in a 2nd clock cycle of pull-down calibration processing; or
perform an addition by one operation on an internal bit of the pull-down control code if the resistance comparison signal is in the eighth state in a 1st clock cycle of pull-down calibration processing, and perform a subtraction by one operation on the internal bit of the pull-down control code if the resistance comparison signal is in the seventh state in a 2nd clock cycle of pull-down calibration processing; and
the internal bit of the pull-down control code is a smallest bit of the pull-down control code, and the internal bit of the pull-down control code is not open to a user.

13. The resistance calibration circuit according to any one of claim 8, wherein in the short calibration mode, the pull-up calibration processing occupies two clock cycles; and correspondingly, when the mode selection signal is in the sixth state:
the adjustment module is specifically configured to: perform a subtraction by one operation on an internal bit of the pull-up control code if the resistance comparison signal is in the seventh state in a 1st clock cycle of pull-up calibration processing, and continue to perform the subtraction by one operation on the internal bit of the pull-up control code if the resistance comparison signal is still in the seventh state in a 2nd clock cycle of pull-up calibration processing; or
perform a subtraction by one operation on an internal bit of the pull-up control code if the resistance comparison signal is in the seventh state in a 1st clock cycle of pull-up calibration processing, and perform an addition by one operation on the internal bit of the pull-up control code if the resistance comparison signal is in the eighth state in a 2nd clock cycle of pull-up calibration processing; or
perform an addition by one operation on an internal bit of the pull-up control code if the resistance comparison signal is in the eighth state in a 1st clock cycle of pull-up calibration processing, and continue to perform the addition by one operation on the internal bit of the pull-up control code if the resistance comparison signal is still in the eighth state in a 2nd clock cycle of pull-up calibration processing; or
perform an addition by one operation on an internal bit of the pull-up control code if the resistance comparison signal is in the eighth state in a 1st clock cycle of pull-up calibration processing, and perform a subtraction by one operation on the internal bit of the pull-up control code if the resistance comparison signal is in the seventh state in a 2nd clock cycle of pull-up calibration processing; and
the internal bit of the pull-up control code is a smallest bit of the pull-up control code, and the internal bit of the pull-up control code is not open to the user.

14. The resistance calibration circuit according to claim 3, wherein
a first state, the third state, the fifth state, and the seventh state are high level states, and the second state, the fourth state, the sixth state, and the eighth state are low level states; and
the logic circuit comprises a NAND gate, and two input terminals of the NAND gate respectively receive the short calibration enable signal and the comparison result signal.

15. A resistance calibration method, the method comprising:
performing calibration processing on a resistance control code in a full calibration mode when a short calibration mode is disabled; or performing calibration processing on a resistance control code in a short calibration mode if a last latched value and an initial default value of the resistance control code are different when the short calibration mode is enabled; or performing calibration processing on a resistance control code in a full calibration mode if a last latched value and the initial default value of the resistance control code are the same when a short calibration mode is enabled; and
performing latching processing on the resistance control code after calibration processing is completed, the resistance control code being configured to adjust resistance of a resistor unit.

16. The resistance calibration method according to claim 15, wherein the resistance control code comprises a pull-down control code, the pull-down control code is configured to adjust pull-down resistance of the resistor unit, the calibration processing comprises pull-down calibration processing, and the pull-down calibration processing occupies two clock cycles;
the performing calibration processing on a resistance control code in a short calibration mode comprises:
performing a subtraction by one operation on an internal bit of the pull-down control code if the pull-down resistance of the resistor unit is greater than standard resistance in a 1st clock cycle of pull-down calibration processing, and continuing to perform the subtraction by one operation on the internal bit of the pull-down control code if the pull-down resistance of the resistor unit is still greater than the standard resistance in a 2nd clock cycle of pull-down calibration processing; or
performing a subtraction by one operation on an internal bit of the pull-down control code if the pull-down resistance of the resistor unit is greater than standard resistance in a 1st clock cycle of pull-down calibration processing, and performing an addition by one operation on the internal bit of the pull-down control code if the pull-down resistance of the resistor unit is less than the standard resistance in a 2nd clock cycle of pull-down calibration processing; or
performing an addition by one operation on an internal bit of the pull-down control code if the pull-down resistance of the resistor unit is less than standard resistance in a 1st clock cycle of pull-down calibration processing, and continuing to perform the addition by one operation on the internal bit of the pull-down control code if the pull-down resistance of the resistor unit is still less than the standard resistance in a 2nd clock cycle of pull-down calibration processing; or
performing an addition by one operation on an internal bit of the pull-down control code if the pull-down resistance of the resistor unit is less than standard resistance in a 1st clock cycle of pull-down calibration processing, and performing a subtraction by one operation on the internal bit of the pull-down control code if the pull-down resistance of the resistor unit is greater than the standard resistance in a 2nd clock cycle of pull-down calibration processing; and
the internal bit of the pull-down control code is a smallest bit of the pull-down control code, and the internal bit of the pull-down control code is not open to a user.

17. The resistance calibration method according to claim 15, wherein the resistance control code further comprises a pull-up control code, the pull-up control code is configured to adjust pull-up resistance of the resistor unit, the calibration processing further comprises pull-up calibration processing, and the pull-up calibration processing occupies two clock cycles;
the performing calibration processing on a resistance control code in a short calibration mode further comprises:
performing a subtraction by one operation on an internal bit of the pull-up control code if the pull-up resistance of the resistor unit is less than a standard resistance in a 1st clock cycle of pull-up calibration processing, and continuing to perform the subtraction by one operation on the internal bit of the pull-up control code if the pull-up resistance of the resistor unit is still less than the standard resistance in a 2nd clock cycle of pull-up calibration processing; or
performing a subtraction by one operation on an internal bit of the pull-up control code if the pull-up resistance of the resistor unit is less than the standard resistance in a 1st clock cycle of pull-up calibration processing, and performing an addition by one operation on the internal bit of the pull-up control code if the pull-up resistance of the resistor unit is greater than the standard resistance in a 2nd clock cycle of pull-up calibration processing; or
performing an addition by one operation on an internal bit of the pull-up control code if the pull-up resistance of the resistor unit is greater than the standard resistance in a 1st clock cycle of pull-up calibration processing, and continuing to perform the addition by one operation on the internal bit of the pull-up control code if the pull-up resistance of the resistor unit is greater than the standard resistance in a 2nd clock cycle of pull-up calibration processing; or
performing an addition by one operation on an internal bit of the pull-up control code if the pull-up resistance of the resistor unit is greater than the standard resistance in a 1st clock cycle of pull-up calibration processing, and performing a subtraction by one operation on the internal bit of the pull-up control code if the pull-up resistance of the resistor unit is less than the standard resistance in a 2nd clock cycle of pull-up calibration processing; and
the internal bit of the pull-up control code is a smallest bit of the pull-up control code, and the internal bit of the pull-up control code is not open to the user.

18. A memory, the memory comprising the resistance calibration circuit, wherein the resistance calibration circuit comprising:
a register circuit, configured to store and output a short calibration enable signal;
a comparison circuit, configured to: receive a last latched value and an initial default value of a resistance control code, perform a consistency comparison between the last latched value and the initial default value of the resistance control code, and output a comparison result signal;
a logic circuit, configured to: receive the short calibration enable signal and the comparison result signal, perform a logical operation on the short calibration enable signal and the comparison result signal, and output a mode selection signal; and
a calibration circuit, configured to: perform calibration processing on the resistance control code in one of a short calibration mode and a full calibration mode based on the mode selection signal when a calibration start signal is received, and perform latching processing on the resistance control code after calibration processing is completed; and
both the register circuit and the comparison circuit being connected to the logic circuit, and the logic circuit being connected to the calibration circuit.
